(19) United States
(12) Patent Application Publication
(10) Pub. No.: US 2025/0120202 A1
(43) Pub. Date: Apr. 10, 2025

(54) IMAGING DEVICE

(71) Applicant: SONY SEMICONDUCTOR SOLUTIONS CORPORATION, KANAGAWA (JP)

(72) Inventor: KAZUYA SUGIMURA, KANAGAWA (JP)

(21) Appl. No.: 18/694,732

(22) PCT Filed: Sep. 26, 2022
(86) PCT No.: PCT/JP2022/035667

§ 371 Date: Mar. 22, 2024

(30) Foreign Application Priority Data
Oct. 5, 2021 (JP) 2021-163900

(51) Int. Cl. H10F 39/00; H01L 25/04

(52) U.S. Cl. CPC H10F 39/80373; H01L 25/043; H10F 39/809; H10F 39/811

(57) ABSTRACT

An imaging device capable of reducing the capacitance of a transfer gate electrode is provided. The imaging device includes a first substrate and a plurality of pixels provided in the first substrate. Each of the plurality of pixels includes a photoelectric conversion portion provided in the first substrate, a charge storage portion provided in the first substrate, and a transfer transistor provided on a first surface side of the first substrate to transfer charges from the photoelectric conversion portion to the charge storage portion. The transfer transistor includes a transfer gate electrode provided on the first surface of the first substrate via an insulating film interposed between the transfer gate electrode and the first surface. The insulating film includes a first insulating film located on a channel region formed on the first substrate, and a second insulating film located on a region other than the channel region on the first substrate. The second insulating film is thicker than the first insulating film.

### TECHNICAL FIELD

The present disclosure relates to an imaging device.

### BACKGROUND ART

A solid-state imaging device is known, including a semiconductor substrate including an element formation section; a signal charge accumulation portion formed inside the element formation section, and a gate electrode that controls transfer of a group of signal charges accumulated in the signal charge accumulation section (e.g., see PTL 1).

### CITATION LIST

### Patent Literature

[PTL 1]
JP 2006-286848A

### SUMMARY

### Technical Problem

For a large capacitance between the gate electrode that controls the transfer of a group of signal charges (hereinafter also referred to as a transfer gate electrode) and the semiconductor substrate, the settling time of a transistor including the transfer gate electrode (hereinafter also referred to as a transfer transistor) increases, making it difficult to increase the speed of the transfer transistor.

The present disclosure has been made in view of such circumstances and an object thereof is to provide an imaging device capable of reducing the capacitance of a transfer gate electrode.

### Solution to Problem

An imaging device according to one aspect of the present disclosure includes a first substrate and a plurality of pixels that are provided in the first substrate. Each of the plurality of pixels includes a photoelectric conversion portion that is provided in the first substrate, a charge storage portion that is provided in the first substrate, and a transfer transistor that is provided on a first surface side of the first substrate to transfer charges from the photoelectric conversion portion to the charge storage portion. The transfer transistor includes a transfer gate electrode that is provided on the first surface of the first substrate via an insulating film interposed between the transfer gate electrode and the first surface. The insulating film includes a first insulating film that is located on a channel region formed on the first substrate, and a second insulating film that is located on a region other than the channel region on the first substrate. The second insulating film is thicker than the first insulating film.

According to this, it is possible to reduce a part of a capacitance generated between the transfer gate electrode and the first substrate, the part being a capacitance between a portion located on the second insulating film (e.g., a second conductor portion) and the first substrate. As a result, the capacitance of the transfer gate electrode can be reduced compared to a case where the first insulating film and the second insulating film have the same thickness.

An imaging device according to another aspect of the present disclosure includes a first substrate and a plurality of pixels provided in the first substrate. Each of the plurality of pixels includes a photoelectric conversion portion that is provided in the first substrate, a charge storage portion that is provided in the first substrate, and a transfer transistor that is provided on a first surface side of the first substrate to transfer charges from the photoelectric conversion portion to the charge storage portion. The transfer transistor includes a transfer gate electrode that is provided on the first surface of the first substrate via an insulating film interposed between the transfer gate electrode and the first surface. The transfer gate electrode includes a first conductor portion and a second conductor portion that is connected to the first conductor portion. The insulating film includes a first insulating film that is located between the first substrate and the first conductor portion, and a second insulating film that is located between the first substrate and the second conductor portion. The second insulating film is thicker than the first insulating film.

According to this, it is possible to reduce a portion of a capacitance generated between the transfer gate electrode and the first substrate, the portion being a capacitance between the second conductor portion and the first substrate. As a result, the capacitance of the transfer gate electrode can be reduced compared to a case where the first insulating film and the second insulating film have the same thickness.

### BRIEF DESCRIPTION OF DRAWINGS

FIG. 1 is a plan view illustrating a schematic configuration example of an imaging device according to an embodiment of the present disclosure.

FIG. 2 is a cross-sectional view illustrating a schematic configuration example of the imaging device according to the embodiment of the present disclosure.

FIG. 3 is an equivalent circuit diagram illustrating a configuration example of a pixel share unit according to the embodiment of the present disclosure.

FIG. 4 is a cross-sectional view illustrating a configuration example of the imaging device according to the embodiment of the present disclosure.

FIG. 5 is a plan view illustrating a configuration example of a pixel share unit according to the embodiment of the present disclosure.

FIG. 6 is a plan view illustrating an arrangement example of a plurality of pixel share units according to the embodiment of the present disclosure.

FIG. 7A is a plan view illustrating a configuration example of a pixel according to the embodiment of the present disclosure.

FIG. 7B is a cross-sectional view illustrating the configuration example of the pixel according to the embodiment of the present disclosure.

FIG. 8 is a cross-sectional view illustrating a configuration example of a pixel according to a comparative example of the present disclosure.

FIG. 9 is a plan view illustrating Modification example 1 of a pixel according to the embodiment of the present disclosure.

FIG. 10 is a plan view illustrating Modification example 2 of a pixel according to the embodiment of the present disclosure.

FIG. 11A is a plan view illustrating Modification example 3 of a pixel according to the embodiment of the present disclosure.

FIG. 11B is a cross-sectional view illustrating Modification example 3 of the pixel according to the embodiment of the present disclosure.

FIG. 12A is a plan view illustrating Modification example 4 of a pixel according to the embodiment of the present disclosure.

FIG. 12B is a cross-sectional view illustrating Modification example 4 of the pixel according to the embodiment of the present disclosure.

FIG. 13 is a diagram illustrating an example of a schematic configuration of an imaging system 7 including the imaging device 1 according to the embodiment and the modification examples.

FIG. 14 is a flowchart illustrating an example of an imaging operation in the imaging system 7.

FIG. 15 is a block diagram illustrating a schematic configuration example of a vehicle control system that is an example of a moving body control system to which the technology according to the present disclosure may be applied.

FIG. 16 is a diagram illustrating an example of installation positions of imaging units 12031.

FIG. 17 is a diagram illustrating an example of a schematic configuration of an endoscopic surgery system to which the technology according to the present disclosure (the present technology) may be applied.

FIG. 18 is a block diagram illustrating an example of a functional configuration of a camera head 11102 and a CCU 11201, which are illustrated in FIG. 17.

### DESCRIPTION OF EMBODIMENTS

Embodiments of the present disclosure will be described below with reference to the drawings. In descriptions of the drawings referred to in the following description, same or similar portions will be denoted by same or similar reference signs. However, it should be noted that the drawings are schematic and relationships between thicknesses and planar dimensions, ratios of thicknesses of respective layers, and the like are different from actual ones. Accordingly, specific thicknesses and dimensions should be determined by taking the following description into consideration. In addition, it goes without saying that the drawings also include portions having different dimensional relationships and ratios from each other.

### (Schematic Configuration Example of Imaging Device)

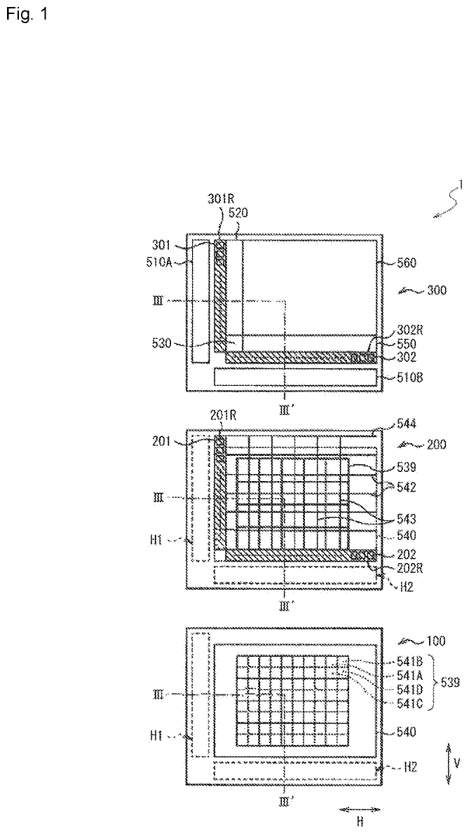

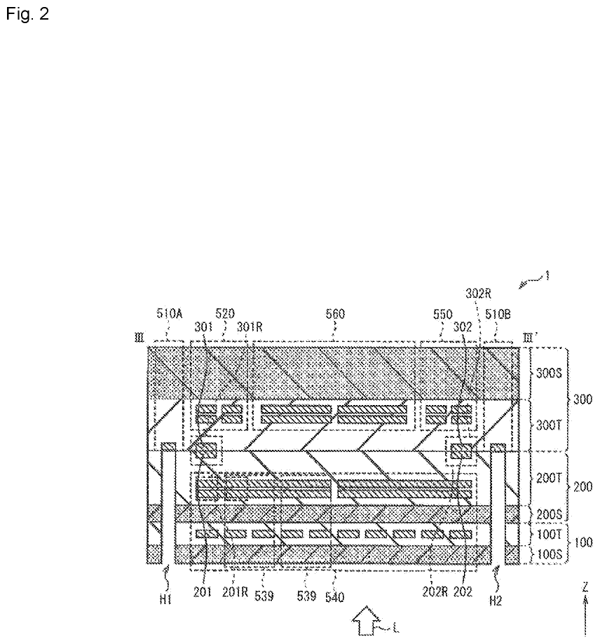

FIG. 1 is a plan view illustrating a schematic configuration example of an imaging device 1 according to an embodiment of the present disclosure, and is also a diagram schematically illustrating a plan configuration of each of a first substrate 100, a second substrate 200, and a third substrate 300. FIG. 2 is a cross-sectional view illustrating a schematic configuration example of the imaging device 1 according to the embodiment of the present disclosure, and is also a diagram schematically illustrating a cross section of a three-dimensional structure, taken along line III-III′, in which the three substrates (the first substrate 100, the second substrate 200, and the third substrate 300) illustrated in FIG. 1 are bonded together.

As illustrated in FIGS. 1 and 2, the imaging device 1 includes the three substrates (the first substrate 100, the second substrate 200, and the third substrate 300). The first substrate 100 includes a semiconductor layer 100S and a wiring layer 100T. The second substrate 200 includes a semiconductor layer 200S and a wiring layer 200T. The third substrate 300 includes a semiconductor layer 300S and a wiring layer 300T. For convenience, a set of wires included in each of the first substrate 100, the second substrate 200, and the third substrate 300 and an interlayer insulating film surrounding the wires is hereinafter referred to as a wiring layer (100T, 200T, 300T) provided in the corresponding substrate (the first substrate 100, the second substrate 200, and the third substrate 300).

The first substrate 100, the second substrate 200, and the third substrate 300 are laminated one on another in this order, and the semiconductor layer 100S, the wiring layer 100T, the semiconductor layer 200S, the wiring layer 200T, the wiring layer 300T, and the semiconductor layer 300S are arranged in this order along a lamination direction (Z direction). A specific configuration of the first substrate 100, the second substrate 200, and the third substrate 300 will be described later.

The arrow illustrated in FIG. 2 represents a direction of incidence of light L into the imaging device 1. As used herein, for convenience, in the following cross-sectional views, the light incidence side of the imaging device 1 is sometimes referred to as “lower”, “lower side”, and “below”, and the side opposite to the light incidence side is sometimes referred to as “upper”, “upper side”, and “above”. Further, in this specification, for convenience, with respect to a substrate including a semiconductor layer and a wiring layer, the wiring layer side is sometimes referred to as a front surface, and the semiconductor layer side is sometimes referred to as a back surface. The terms as used herein are not limited to the references defined above. The imaging device 1 is a back-illuminated imaging device in which, for example, light enters from the back surface side of the first substrate 100 including photodiodes.

A pixel array unit 540 is configured using the first substrate 100 and the second substrate 200. In the pixel array unit 540, a plurality of pixels 541 are repeatedly arranged in an array. More specifically, pixel share units 539 each including a plurality of pixels 541 serve as repeating units, which are repeatedly arranged in an array in a row direction and a column direction. As used herein, for convenience, the row direction is sometimes referred to as the H direction, and the column direction orthogonal to the row direction is sometimes referred to as the V direction.

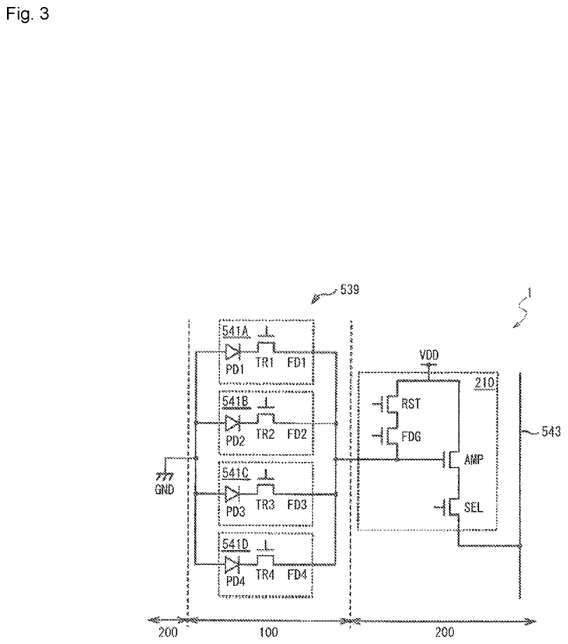

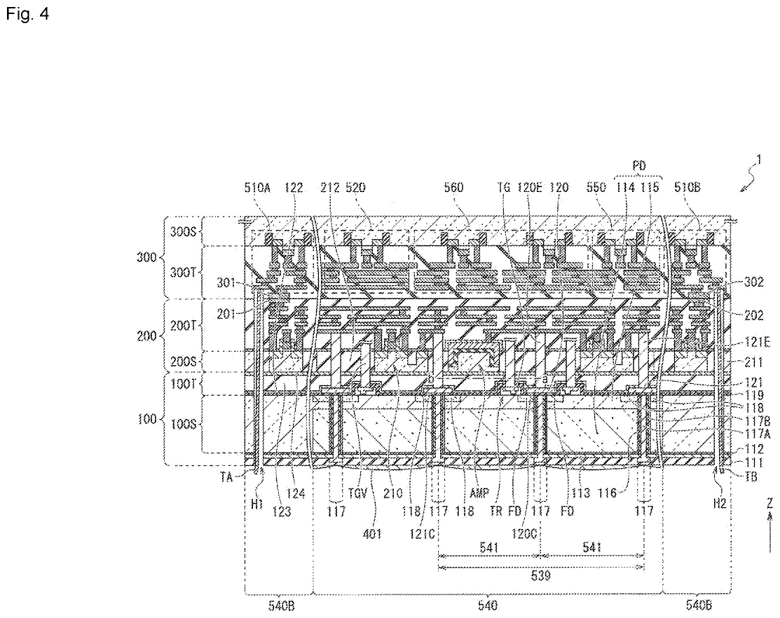

In the example illustrated in FIG. 1, one pixel share unit 539 includes four pixels (pixels 541A, 541B, 541C, and 541D). Each of the pixels 541A, 541B, 541C, and 541D includes a photodiode PD (illustrated in FIG. 4, etc., which will be described later). The pixel share unit 539 is a unit that shares one pixel circuit (a pixel circuit 210 in FIG. 3, which will be described later). In other words, each of the four pixels (the pixels 541A, 541B, 541C, and 541D) includes one pixel circuit (the pixel circuit 210, which will be described later). By operating this pixel circuit in a time-division manner, the pixel signals of the pixels 541A, 541B, 541C, and 541D are sequentially read out.

The pixels 541A, 541B, 541C, and 541D are arranged, for example, in two rows and two columns. The pixel array unit 540 includes the pixels 541A, 541B, 541C, and 541D, as well as a plurality of row drive signal lines 542 and a plurality of vertical signal lines (column readout lines) 543. Row drive signal lines 542 drive the pixels 541 included in each of the plurality of pixel share units 539 arranged in the row direction in the pixel array unit 540. As will be described in detail later with reference to FIG. 3, the pixel share unit 539 includes a plurality of transistors. A plurality of row drive signal lines 542 are connected to one pixel share unit 539 in order to drive these plurality of transistors, respectively. Pixel signals are read out from the pixels 541A, 541B, 541C, and 541D included in the pixel share unit 539 via a vertical signal line (a column readout line) 543, respectively.

For example, on the first substrate 100, the plurality of pixels 541A, 541B, 541C, and 541D included in each pixel share unit 539 are provided. The second substrate 200 is provide with a pixel circuit (the pixel circuits 210, which will be described later) included in each pixel share unit 539, a plurality of row drive signal lines 542 extending in the row direction, a plurality of vertical signal lines 543 extending in the column direction, and power supply lines 544 extending in the row direction. The third substrate 300 is provided with, for example, an input unit 510A, a row drive unit 520, a timing control unit 530, a column signal processing unit 550, an image signal processing unit 560, and an output unit 510B. The row drive unit 520 is provided, for example, in a region partially overlapping the pixel array unit 540 in the direction (Z direction) in which the first substrate 100, the second substrate 200, and the third substrate 300 are laminated.

The pixel circuit provided in the second substrate 200 is also sometimes referred to as a pixel transistor circuit, a pixel transistor group, a pixel transistor, a pixel readout circuit, or a readout circuit, as another name. The term “pixel circuit” is used herein.

The first substrate 100 and the second substrate 200 are electrically connected by, for example, through electrodes (through electrodes 120E and 121E in FIG. 4, which will be described later). The second substrate 200 and the third substrate 300 are electrically connected via, for example, contact portions 201, 202, 301, and 302. The contact portions 201 and 202 are provided on the second substrate 200, and the contact portions 301 and 302 are provided on the third substrate 300. The contact portion 201 of the second substrate 200 is in contact with the contact portion 301 of the third substrate 300, and the contact portion 202 of the second substrate 200 is in contact with the contact portion 302 of the third substrate 300. The second substrate 200 has a contact region 201R in which a plurality of contact portions 201 are provided and a contact region 202R in which a plurality of contact portions 202 are provided. The third substrate 300 has a contact region 301R in which a plurality of contact portions 301 are provided and a contact region 302R in which a plurality of contact portions 302 are provided.

The contact regions 201R and 301R are provided between the pixel array unit 540 and the row drive unit 520 in the lamination direction (Z direction). The contact portions 201 and 301 in the contact regions 201R and 301R connect, for example, the row drive unit 520 provided in the third substrate 300 and the row drive signal line 542 provided in the second substrate 200. The contact portions 201 and 301 may connect, for example, the input unit 510A provided in the third substrate 300 to the power supply line 544 and a reference potential line (a reference potential line VSS, which will be described later).

The contact regions 202R and 302R are provided between the pixel array unit 540 and the column signal processing unit 550 in the lamination direction (Z direction). The contact portions 202 and 302 in the contact regions 202R and 302R connect, for example, to the column signal processing unit 550 provided in the third substrate 300, a pixel signal (a signal corresponding to the amount of charges generated as a result of photoelectric conversion in a photodiode) output from each of the plurality of pixel share units 539 included in the pixel array unit 540. The pixel signal is sent from the second substrate 200 to the third substrate 300.

The contact portions 201, 202, 301, and 302 are made of a metal material such as copper (Cu), aluminum (Al), or gold (Au), for example.

The first substrate 100 and the second substrate 200 are provided with, for example, connection hole portions H1 and H2. The connection hole portions H1 and H2 penetrate through the first substrate 100 and the second substrate 200. The connection hole portions H1 and H2 are provided outside the pixel array unit 540 (or a portion overlapping the pixel array unit 540). For example, the connection hole portion H1 is placed outside the pixel array unit 540 in the H direction, and the connection hole portion H2 is placed outside the pixel array unit 540 in the V direction. For example, the connection hole portion H1 reaches the input unit 510A provided in the third substrate 300, and the connection hole portion H2 reaches the output unit 510B provided in the third substrate 300. The connection hole portions H1 and H2 may be hollow, or may contain a conductive material at least in part. For example, there is provided a configuration in which electrodes formed as the input unit 510A and/or the output unit 510B are connected to bonding wires. Alternatively, there is provided a configuration in which electrodes formed as the input unit 510A and/or the output unit 510B are connected to conductive materials provided in the connection hole portions H1 and H2. The conductive material provided in the connection hole portions H1 and H2 may be embedded in part or all of the connection hole portions H1 and H2, or the conductive material may be formed on the side walls of the connection hole portions H1 and H2.

FIG. 3 is an equivalent circuit diagram illustrating a configuration example of the pixel share unit 539 according to the embodiment of the present disclosure. The pixel share unit 539 includes the plurality of pixels 541 (represented as four pixels 541: pixels 541A, 541B, 541C, and 541D in FIG. 3), one pixel circuit 210 connected to the plurality of pixels 541, and the vertical signal line 543 connected to the pixel circuit 210. The pixel circuit 210 includes, for example, four transistors, specifically, an amplifier transistor AMP, a selection transistor SEL, a reset transistor RST, and an FD conversion gain switching transistor FDG.

As described above, the pixel share unit 539 operates one pixel circuit 210 in a time-division manner to sequentially output pixel signals of the four pixels 541 (the pixels 541A, 541B, 541C, and 541D) included in the pixel share unit 539 to the vertical signal line 543. An aspect in which one pixel circuit 210 is connected to a plurality of pixels 541, and the pixel signals of the plurality of pixels 541 are outputted by the one pixel circuit 210 in a time-division manner means that “the plurality of pixels 541 share the one pixel circuit 210”.

The pixels 541A, 541B, 541C, and 541D have common constituent elements. Hereinafter, in order to distinguish the constituent elements of the pixels 541A, 541B, 541C, and 541D from each other, identification number 1 is given as a suffix for the reference character of each constituent element of the pixel 541A, identification number 2 is given as a suffix for the reference character of each constituent element of the pixel 541B, identification number 3 is given as a suffix for the reference character of each constituent element of the pixel 541C, and identification number 4 is given as a suffix for the reference character of each constituent element of the pixel 541D. If there is no need to distinguish the constituent elements of the pixels 541A, 541B, 541C, and 541D from each other, the identification numbers as suffixes for the reference characters of the constituent elements of the pixels 541A, 541B, 541C, and 541D will be omitted.

The pixels 541A, 541B, 541C, and 541D each include, for example, a photodiode PD, a transfer transistor TR electrically connected to the photodiode PD, and a floating diffusion FD electrically connected to the transfer transistor TR. In the photodiode PD (PD1, PD2, PD3, PD4), the cathode is electrically connected to the source of the transfer transistor TR, and the anode is electrically connected to a reference potential line (e.g., ground).

The photodiode PD photoelectrically converts incident light to generate charges corresponding to the amount of light received. The transfer transistor TR (transfer transistor TR1, TR2, TR3, TR4) are, for example, an n-type metal oxide semiconductor (MOS) transistor. In the transfer transistor TR, the drain is electrically connected to the floating diffusion FD, and the gate is electrically connected to a drive signal line. This drive signal line is one of the plurality of row drive signal lines 542 connected to one pixel share unit 539. The transfer transistor TR transfers the charges generated in the photodiode PD to the floating diffusion FD. The floating diffusion FD (floating diffusion FD1, FD2, FD3, FD4) is an n-type diffusion layer region formed in a p-type semiconductor layer. The floating diffusion FD is a charge holding means that temporarily holds the charges transferred from the photodiode PD, and is also a charge-voltage conversion means that generates a voltage corresponding to the amount of charges.

The four floating diffusions FD (floating diffusions FD1, FD2, FD3, FD4) included in one pixel share unit 539 are electrically connected to each other, and are electrically connected to the gate of the amplifier transistor AMP and the source of the FD conversion gain switching transistor FDG. The drain of the FD conversion gain switching transistor FDG is connected to the source of the reset transistor RST, and the gate of the FD conversion gain switching transistor FDG is connected to a drive signal line. This drive signal line is one of the plurality of row drive signal lines 542 connected to the one pixel share unit 539.

The drain of the reset transistor RST is connected to a power supply line VDD, and the gate of the reset transistor RST is connected to a drive signal line. This drive signal line is one of the plurality of row drive signal lines 542 connected to the one pixel share unit 539. The gate of the amplifier transistor AMP is connected to the floating diffusion FD, the drain of the amplifier transistor AMP is connected to the power supply line VDD, and the source of the amplifier transistor AMP is connected to the drain of the selection transistor SEL. The source of the selection transistor SEL is connected to the vertical signal line 543, and the gate of the selection transistor SEL is connected to a drive signal line. This drive signal line is one of the plurality of row drive signal lines 542 connected to the one pixel share unit 539.

When the transfer transistor TR is turned on, the transfer transistor TR transfers the charges of the photodiode PD to the floating diffusion FD. The gate of the transfer transistor TR (transfer gate electrode TG) includes, for example, a so-called vertical electrode, and extends from the front surface of a semiconductor layer (a semiconductor layer 100S in FIG. 4, which will be described later) with a depth to reach the PD, as illustrated in FIG. 4.

The reset transistor RST resets the potential of the floating diffusion FD to a predetermined potential. When the reset transistor RST is turned on, the potential of the floating diffusion FD is reset to the potential of the power supply line VDD. The selection transistor SEL controls the output timing of a pixel signal from the pixel circuit 210. The amplifier transistor AMP generates a voltage signal serving as a pixel signal in accordance with the level of the electric charges held in the floating diffusion FD.

The amplifier transistor AMP is connected to the vertical signal line 543 via the selection transistor SEL. When the selection transistor SEL is turned on, the amplifier transistor AMP outputs the voltage of the floating diffusion FD to the vertical signal line 543. The reset transistor RST, the amplifier transistor AMP, and the selection transistor SEL are, for example, n-type MOS transistors.

The FD conversion gain switching transistor FDG is used to change the charge-voltage conversion gain for the floating diffusion FD. In general, pixel signals from image capture in a dark place are low. For charge-voltage conversion performed based on Q=CV, if the capacitance of the floating diffusion FD (FD capacitance C) is large, V, which is a voltage into which the amplifier transistor AMP converts the charges, will be low. On the other hand, pixel signals in a bright place are high, and therefore, the floating diffusion FD cannot receive all the charges of the photodiode PD unless the FD capacitance C is large. Furthermore, the FD capacitance C needs to be large so that V, which is a voltage into which the amplifier transistor AMP converts, will not be too high (in other words, will be low).

In the imaging device 1, when the FD conversion gain switching transistor FDG is turned on, the gate capacitance of the FD conversion gain switching transistor FDG is added, and thus, the overall FD capacitance C increases. On the other hand, when the FD conversion gain switching transistor FDG is turned off, the overall FD capacitance C becomes smaller. In this way, by switching the FD conversion gain switching transistor FDG on and off, the FD capacitance C can be made variable so that the conversion efficiency can be switched. The FD conversion gain switching transistor FDG is, for example, an n-type MOS transistor.

The imaging device 1 may have a configuration in which the FD conversion gain switching transistor FDG is not provided. In this case, for example, the pixel circuit 210 is configured with three transistors: an amplifier transistor AMP, a selection transistor SEL, and a reset transistor RST. The pixel circuit 210 includes, for example, at least one pixel transistor such as an amplifier transistor AMP, a selection transistor SEL, a reset transistor RST, and an FD conversion gain switching transistor FDG.

The selection transistor SEL may be provided between the power supply line VDD and the amplifier transistor AMP. In this case, the drain of the reset transistor RST is electrically connected to the power supply line VDD and the drain of the selection transistor SEL. The source of the selection transistor SEL is electrically connected to the drain of the amplifier transistor AMP, and the gate of the selection transistor SEL is electrically connected to a row drive signal line 542. The source of the amplifier transistor AMP (the output end of the pixel circuit 210) is electrically connected to the vertical signal line 543, and the gate of the amplifier transistor AMP is electrically connected to the source of the reset transistor RST. Although not illustrated, the number of pixels 541 that share one pixel circuit 210 may be other than four. For example, two or eight pixels 541 may share one pixel circuit 210.

### (Configuration Example of Imaging Device)

FIG. 4 is a cross-sectional view illustrating a configuration example of the imaging device 1 according to the embodiment of the present disclosure, and also illustrates an example of a cross-sectional configuration in a direction perpendicular to the main surfaces of the first substrate 100, the second substrate 200, and the third substrate 300. FIG. 4 is a schematic representation to make it easier to understand the positional relationship of the constituent elements, and may differ from the actual cross section. In the imaging device 1, the first substrate 100, the second substrate 200, and the third substrate 300 are laminated one on another in this order. The imaging device 1 further includes light receiving lenses 401 on the back surface side (light incident surface side) of the first substrate 100. A color filter layer (not illustrated) may be provided between the light receiving lens 401 and the first substrate 100. The light receiving lens 401 is provided in each of the pixels 541A, 541B, 541C, and 541D, for example. The imaging device 1 is, for example, a back-illuminated imaging device. The imaging device 1 includes the pixel array unit 540 centered and a peripheral unit 540B arranged outside the pixel array unit 540.

The first substrate 100 includes, in order from the light receiving lens 401 side, an insulating film 111, a fixed charge film 112, the semiconductor layer 100S, and the wiring layer 100T. The semiconductor layer 100S is made from, for example, a silicon substrate. The semiconductor layer 100S has, for example, a P-well layer 115 in a part of and near the front surface (the surface on the wiring layer 100T side), and an n-type semiconductor region 114 in the other region (a region deeper than the P-well layer 115). For example, the n-type semiconductor region 114 and the P-well layer 115 form a pn junction photodiode PD. The P-well layer 115 is a p-type semiconductor region.

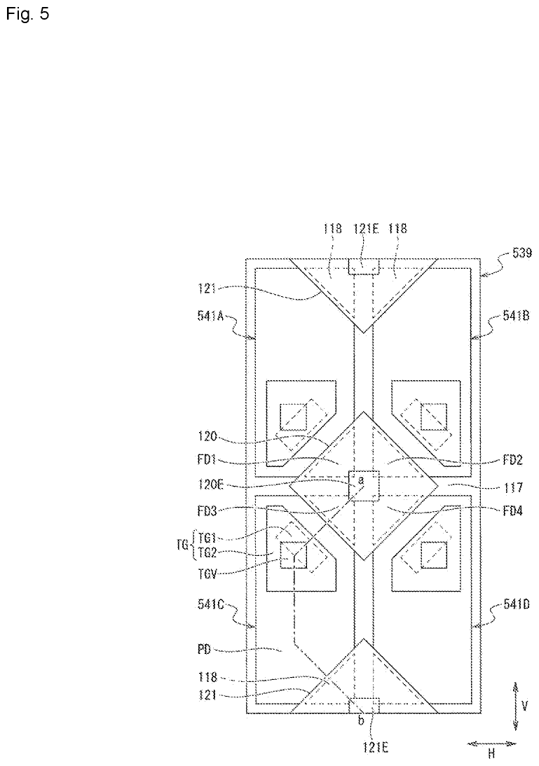

A floating diffusion FD and a VSS contact region 118 are provided near the front surface of the semiconductor layer 100S. The floating diffusion FD is formed of an n-type semiconductor region provided within the P-well layer 115. The floating diffusions FD (floating diffusions FD1, FD2, FD3, and FD4) of the pixels 541A, 541B, 541C, and 541D are provided close to each other, for example, in a central portion of the pixel share unit 539. This configuration will be described in more detail later with reference to FIG. 5.

The VSS contact region 118 is a region electrically connected to a reference potential line VSS, and is arranged apart from the floating diffusion FD. For example, in the pixels 541A, 541B, 541C, and 541D, a floating diffusion FD is arranged at one end of each pixel in the V direction, and a VSS contact region 118 is arranged at the other end. The VSS contact region 118 is formed of, for example, a p-type semiconductor region. The VSS contact region 118 is connected to, for example, a ground potential or a fixed potential. This allows the reference potential to be supplied to the semiconductor layer 100S.

The first substrate 100 is provided with transfer transistors TR as well as the photodiodes PD, the floating diffusions FD, and the VSS contact regions 118. The photodiode PD, the floating diffusion FD, the VSS contact region 118, and the transfer transistor TR are provided in each of the pixels 541A, 541B, 541C, and 541D.

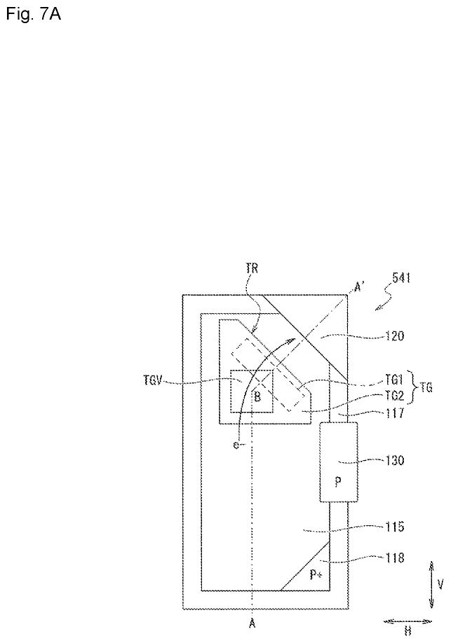

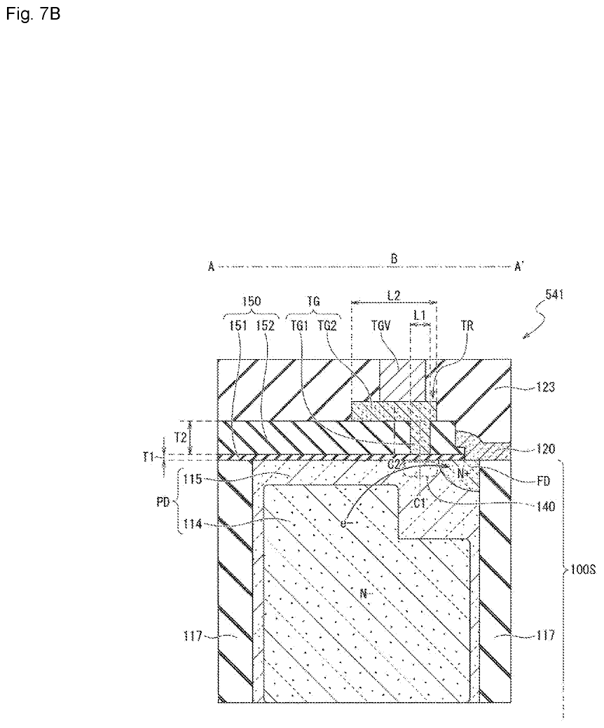

The transfer transistor TR is provided on the front surface side of the semiconductor layer 100S (the side opposite to the light incident surface side, the second substrate 200 side). The transfer transistor TR has a transfer gate electrode TG as a gate electrode. The transfer gate electrode TG has, for example, a first conductor portion and a second conductor portion connected to the first conductor portion. The configuration of the transfer gate electrode TG will be described in more detail later with reference to FIGS. 7A and 7B.

In the semiconductor layer 100S, a pixel separating portion 117 is provided that separates the pixels 541A, 541B, 541C, and 541D from each other. The pixel separating portion 117 is formed to extend in the normal direction of the semiconductor layer 100S (a direction perpendicular to the front surface of the semiconductor layer 100S). The pixel separating portion 117 is provided so as to partition the pixels 541A, 541B, 541C, and 541D from each other, and has, for example, a grid-like planar shape (see FIG. 5 described later).

The pixel separating portion 117 electrically and optically isolates the pixels 541A, 541B, 541C, and 541D from each other, for example. The pixel separating portion 117 includes, for example, a light shielding film 117A and an insulating film 117B. For example, tungsten (W) or the like is used for the light shielding film 117A. The insulating film 117B is provided between the light shielding film 117A and the P-well layer 115 or the n-type semiconductor region 114. The insulating film 117B is made of, for example, silicon oxide (SiO).

The pixel separating portion 117 has, for example, a full trench isolation (FTI) structure, and penetrates through the semiconductor layer 100S. Although not illustrated, the pixel separating portion 117 is not limited to the FTI structure, which penetrates through the semiconductor layer 100S. For example, a deep trench isolation (DTI) structure that does not penetrate through the semiconductor layer 100S may be used. The pixel separating portion 117 is formed in a part of the semiconductor layer 100S so as to extend in the normal direction of the semiconductor layer 100S.

In the semiconductor layer 100S, for example, a first pinning region 113 and a second pinning region 116 are provided. The first pinning region 113 is provided near the back surface of the semiconductor layer 100S, and is arranged between the n-type semiconductor region 114 and the fixed charge film 112. The second pinning region 116 is provided on the side surfaces of the pixel separating portion 117, specifically between the pixel separating portion 117 and the P-well layer 115 or the n-type semiconductor region 114. The first pinning region 113 and the second pinning region 116 are formed of, for example, a p-type semiconductor region.

The fixed charge film 112 having negative fixed charges is provided between the semiconductor layer 100S and the insulating film 111. An electric field induced by the fixed charge film 112 forms the first pinning region 113, which is a hole accumulation layer, at the interface on the light-receiving surface (back surface) side of the semiconductor layer 100S. This suppresses the generation of dark current caused by the interface level on the light-receiving surface side of the semiconductor layer 100S. The fixed charge film 112 is formed of, for example, an insulating film having negative fixed charges. Examples of the material of the insulating film having negative fixed charges include hafnium oxide, zirconium oxide, aluminum oxide, titanium oxide, and tantalum oxide.

The light shielding film 117A is provided between the fixed charge film 112 and the insulating film 111. The light shielding film 117A may be provided continuously with the light shielding film 117A forming the pixel separating portion 117. The light shielding film 117A between the fixed charge film 112 and the insulating film 111 is selectively provided, for example, at a position facing the pixel separating portion 117 in the semiconductor layer 100S. The insulating film 111 is provided to cover the light shielding film 117A. The insulating film 111 is made of, for example, silicon oxide.

The wiring layer 100T provided between the semiconductor layer 100S and the second substrate 200 includes an interlayer insulating film 119, pad portions 120 (an example of a “shared conductor” according to the present disclosure) and 121, a passivation film 122, an interlayer insulating film 123, and a bonding film 124 in this order from the semiconductor layer 100S side. The transfer gate electrode TG is provided, for example, in the wiring layer 100T. The interlayer insulating film 119 is provided over the entire front surface of the semiconductor layer 100S and is in contact with the semiconductor layer 100S. The interlayer insulating film 119 is formed of, for example, a silicon oxide film. The configuration of the wiring layer 100T is not limited to the above-described configuration, and may be any configuration as long as it includes wires and an insulating film.

The pad portion 120 is selectively provided on the interlayer insulating film 119. The pad portion 120 connects the floating diffusions FD (floating diffusions FD1, FD2, FD3, FD4) of the pixels 541A, 541B, 541C, and 541D to each other.

The interlayer insulating film 119 is provided with connection vias 120C for electrically connecting the pad portions 120 and the floating diffusions FD1, FD2, FD3, and FD4. The connection via 120C is provided for each of the pixels 541A, 541B, 541C, and 541D. For example, a part of the pad portion 120 is embedded in each connection via 120C to electrically connect the pad portions 120 to the floating diffusions FD1, FD2, FD3, and FD4.

The pad portions 121 are selectively provided on the interlayer insulating film 119. The pad portion 121 connects the plurality of VSS contact regions 118 to each other. For example, the VSS contact regions 118 provided in the pixels 541C and 541D of one of the pixel share units 539 adjacent in the V direction and the VSS contact regions 118 provided in the pixels 541A and 541B of the other pixel share unit 539 are electrically connected by the pad portions 121. The pad portion 121 is provided, for example, across the pixel separating portion 117, and is arranged to overlap at least a part of each of the four VSS contact regions 118. Specifically, the pad portion 121 is formed in a region that overlaps at least a part of each of the plurality of VSS contact regions 118 and at least a part of the pixel separating portion 117 formed between the plurality of VSS contact regions 118 in a direction perpendicular to the semiconductor layer 100S.

The interlayer insulating film 119 is provided with the connection vias 121C for electrically connecting the pad portions 121 and the VSS contact regions 118. The connection via 121C is provided for each of the pixels 541A, 541B, 541C, and 541D. For example, a part of the pad portion 121 is embedded in the connection via 121C to electrically connect the pad portions 121 to the VSS contact regions 118. For example, the pad portions 120 and pad portions 121 of the plurality of pixel share units 539 aligned in the V direction are arranged at substantially the same position in the H direction.

The pad portions 120 being provided make it possible to reduce the number of wires for connecting the floating diffusions FD to the pixel circuit 210 (e.g., the gate electrode of the amplifier transistor AMP) in the entire chip. Similarly, the pad portions 121 being provided make it possible to reduce the number of wires for supplying a potential to the VSS contact regions 118 in the entire chip. This makes it possible to reduce the area of the entire chip, suppress electrical interference between wires in the fine pixels, and/or reduce costs due to a reduced number of parts.

The pad portions 120 and 121 can be provided at desired positions in the first substrate 100 and the second substrate 200. Specifically, the pad portions 120 and 121 can be provided in either the wiring layer 100T or an insulating region 212 of the semiconductor layer 200S. In a case where they are provided in the wiring layer 100T, the pad portions 120 and 121 may be brought into direct contact with the semiconductor layer 100S. Specifically, the pad portions 120 and 121 may be directly connected to at least a part of each of the floating diffusions FD and/or each of the VSS contact regions 118. A configuration may be provided in which connection vias 120C and 121C are provided from each of the floating diffusions FD and/or the VSS contact regions 118 connected to the pad portions 120 and 121, and the pad portions 120 and 121 may be provided at desired positions in the wiring layer 100T and the insulating region 212 of the semiconductor layer 200S.

By using the configuration of the pad portions 120 and 121, the number of wires for connecting the first substrate 100 and the second substrate 200 can be significantly reduced. A reduced number of wires makes it possible to secure a large area of the second substrate 200 in which the pixel circuit 210 is formed. Such a secured area of the pixel circuit 210 makes it possible to form a large pixel transistor, contributing to improving image quality by reducing noise and the like.

The pad portions 120 and 121 are made of, for example, polysilicon (Poly Si), more specifically, doped polysilicon to which impurities are added. The pad portions 120 and 121 are preferably made of a conductive material with high heat resistance, such as polysilicon, tungsten (W), titanium (Ti), and titanium nitride (TiN). This makes it possible to form the pixel circuit 210 after bonding the semiconductor layer 200S of the second substrate 200 to the first substrate 100.

The passivation film 122 is provided over the entire front surface of the semiconductor layer 100S so as to cover the pad portions 120 and 121, for example. The passivation film 122 is formed of, for example, a silicon nitride (SiN) film. The interlayer insulating film 123 covers the pad portions 120 and 121 with the passivation film 122 interposed therebetween. The interlayer insulating film 123 is provided, for example, over the entire front surface of the semiconductor layer 100S. The interlayer insulating film 123 is formed of, for example, a silicon oxide (SiO) film. The bonding film 124 is provided on the bonding surface between the first substrate 100 (specifically, the wiring layer 100T) and the second substrate 200. In other words, the bonding film 124 is in contact with the second substrate 200. The bonding film 124 is provided over the entire main surface of the first substrate 100. The bonding film 124 is formed of, for example, a silicon nitride film.

The light receiving lens 401 faces the semiconductor layer 100S with the fixed charge film 112 and the insulating film 111 interposed therebetween, for example. The light receiving lenses 401 are provided, for example, at positions facing the photodiodes PD of the pixels 541A, 541B, 541C, and 541D, respectively.

The second substrate 200 includes the semiconductor layer 200S and the wiring layer 200T in this order from the first substrate 100 side. The semiconductor layer 200S is formed of a silicon substrate. A well region 211 is provided throughout the thickness of the semiconductor layer 200S. The well region 211 is, for example, a p-type semiconductor region. The second substrate 200 is provided with the pixel circuit 210 arranged for each pixel share unit 539. The pixel circuit 210 is provided, for example, on the front surface side (the wiring layer 200T side) of the semiconductor layer 200S. In the imaging device 1, the second substrate 200 is bonded to the first substrate 100 such that the back surface side (the semiconductor layer 200S side) of the second substrate 200 faces the front surface side (the wiring layer 100T side) of the first substrate 100. In other words, the second substrate 200 is bonded face-to-back to the first substrate 100.

The third substrate 300 includes, for example, the wiring layer 300T and the semiconductor layer 300S in this order from the second substrate 200 side. For example, the front surface of the semiconductor layer 300S is placed on the second substrate 200 side. The semiconductor layer 300S is formed of a silicon substrate. Circuits are provided on the front surface side of this semiconductor layer 300S. Specifically, in the front surface side region of the semiconductor layer 300S, at least one or some of, for example, the input unit 510A, the row drive unit 520, the timing control unit 530, the column signal processing unit 550, the image signal processing unit 560, and the output unit 510B are provided. The wiring layer 300T provided between the semiconductor layer 300S and the second substrate 200 includes, for example, an interlayer insulating film, a plurality of wiring layers isolated by the interlayer insulating film, and the contact portions 301 and 302.

The contact portions 301 and 302 are exposed on the front surface of the wiring layer 300T (the surface on the second substrate 200 side), the contact portion 301 is in contact with the contact portion 201 of the second substrate 200, and the contact portion 302 is in contact with the contact portion 202 of the second substrate 200. The contact portions 301 and 302 are electrically connected to the circuits formed in the semiconductor layer 300S (e.g., at least any of the input unit 510A, the row drive unit 520, the timing control unit 530, the column signal processing unit 550, the image signal processing unit 560, and the output unit 510B). The contact portions 301 and 302 are made of metal such as Cu (copper) and aluminum (Al), for example. For example, an external terminal TA is connected to the input unit 510A through the connection hole portion H1, and an external terminal TB is connected to the output unit 510B through the connection hole portion H2.

### (Configuration Example of Pixel Share Unit)

FIG. 5 is a plan view illustrating a configuration example of the pixel share unit 539 according to the embodiment of the present disclosure, and is also a diagram in plan view as viewed from the normal direction of the front surface of the semiconductor layer 100S (see FIG. 4) included in the first substrate 100. The cross-section taken along line a-b in the plan view of FIG. 5 corresponds to the region taken along line a-b in the cross-sectional view illustrated in FIG. 4.

As illustrated in FIG. 5, one pixel share unit 539 includes four pixels 541 (the pixels 541A, 541B, 541C, and 541D). The pixels 541A, 541B, 541C, and 541D each have a photodiode PD. The pixel share unit 539 is a unit for sharing one pixel circuit 210. By operating the pixel circuit 210 in a time-division manner, pixel signals are sequentially read out from the pixels 541A, 541B, 541C, and 541D, respectively. The pixels 541A, 541B, 541C, and 541D are arranged, for example, in two rows and two columns.

The four floating diffusions FD (the floating diffusions FD1, FD2, FD3, and FD4) included in one pixel share unit 539 are arranged close to each other in a central portion of the pixel share unit 539 in plan view. The floating diffusions FD1, FD2, FD3, and FD4 arranged close to each other in the central portion of one pixel share unit 539 are electrically connected to each other via one pad portion 120.

The pad portion 120 is arranged at a central portion of the pixel share unit 539 in plan view for each pixel share unit 539. The pad portion 120 is provided across the pixel separating portion 117 provided between the pixels 541A, 541B, 541C, and 541D, and overlaps at least a part of each of the floating diffusions FD1, FD2, FD3, and FD4.

The through electrode 120E is provided on the pad portion 120 for each pixel share unit 539. The floating diffusions FD1, FD2, FD3, and FD4 are electrically connected to the gate of the amplifier transistor AMP and the source of the FD conversion gain switching transistor FDG, which are provided in the second substrate 200 (see FIG. 4), via the pad portion 120 and the through electrode 120E.

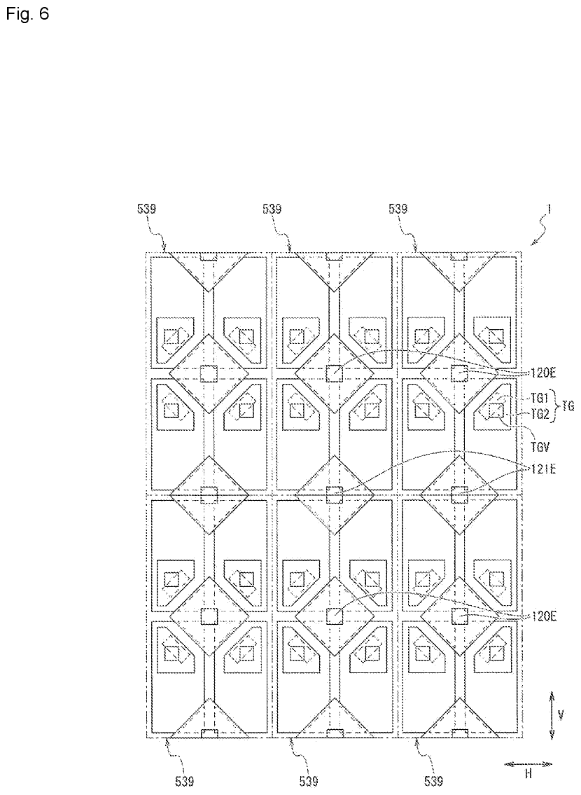

FIG. 6 is a plan view illustrating an arrangement example of a plurality of pixel share units 539 according to the embodiment of the present disclosure. As illustrated in FIG. 6, the plurality of pixel share units 539 are arranged side by side in the row direction (H direction) and the column direction (V direction).

For example, the pad portions 120 to which a plurality of floating diffusions FD are connected and the pad portions 121 to which a plurality of VSS contact regions 118 are connected are alternately arranged linearly in the V direction. In the H direction, the plurality of pad portions 120 and the plurality of pad portions 121 are arranged linearly. The pad portions 120 and 121 are each arranged at a position surrounded by a plurality of photodiodes PD, a plurality of transfer gate electrodes TG, and a plurality of floating diffusions FD.

As a result, in the first substrate 100 in which a plurality of elements are to be formed, elements other than the floating diffusions FD and the VSS contact regions 118 can be freely arranged, so that the layout of the entire chip can be made more efficient. In addition, symmetry in the layout of elements formed in each pixel share unit 539 is ensured, and variations in characteristics of each pixel 541 can be suppressed.

### (Configuration Example of Transfer Transistor)

FIGS. 7A and 7B are a plan view and a cross-sectional view illustrating a configuration example of the pixel 541 according to an embodiment of the present disclosure, respectively. A cross section taken along line A′-B-A in FIG. 7A corresponds to the cross-sectional view in FIG. 7B. As illustrated in FIGS. 7A and 7B, the pixel 541 includes the transfer transistor TR that is provided on the front surface side of the semiconductor layer 100S to transfer a charge e⁻ from the photodiode PD to the floating diffusion FD. The transfer transistor TR has a transfer gate electrode TG provided on the front surface of the semiconductor layer 100S with an insulating film 150 interposed therebetween.

For example, the insulating film 150 includes an insulating film 151 and an insulating film 152 laminated on the insulating film 151. The thickness of the insulating film 152 is thicker than the thickness of the insulating film 151. As an example, each of the insulating films 151 and 152 is a silicon oxide (SiO) film. The thickness T1 of the insulating film 151 is 6.5 nm, and the thickness T2 of the insulating film 152 is 180 nm. The insulating film 151 is a thermal oxide film formed by thermally oxidizing the semiconductor layer 100S. The insulating film 152 is a chemical vapor deposition (CVD) film formed by a CVD method.

The insulating film 151 is located directly above a channel region 140 formed in the semiconductor layer 100S. The insulating films 151 and 152 (that is, a laminated film in which the insulating film 152 is laminated on the insulating film 151) are located in a region other than directly above the channel region 140 in the semiconductor layer 100S.

The transfer gate electrode TG includes a first conductor portion TG1 and a second conductor portion TG2 electrically connected to the first conductor portion TG1. The first conductor portion TG1 is located on the insulating film 151. The second conductor portion TG2 is located on the laminated film in which the insulating film 152 is laminated on the insulating film 151. In other words, the insulating film 151 is located between the semiconductor layer 100S and the first conductor portion TG1, and the above laminated film is located between the semiconductor layer 100S and the second conductor portion TG2.

The first conductor portion TG1 and the first conductor portion TG2 are made of a conductive material, for example, doped polysilicon added with an impurity. The first conductor portion TG1 and the second conductor portion TG2 may be formed at the same time in the same process (i.e., batch formation), or may be formed separately (i.e., the first conductor portion TG1 is formed first, and then the second conductor portion TG2 is formed).

Since the first conductor portion TG1 is closer to the semiconductor layer 100S than the second conductor portion TG2 is, the channel region 140 is formed in the semiconductor layer 100S in a region facing the first conductor portion TG1 with the insulating film 151 interposed therebetween and near the region.

The first conductor portion TG1 is located between the semiconductor layer 100S and the second conductor portion TG2. The second conductor portion TG2 has a larger area than the first conductor portion TG1 in plan view from the normal direction of the semiconductor layer 100S. This makes it possible to secure a large area of the connection of the transfer gate electrode TG to a through electrode TGV, making it easy to arrange the through electrode TGV over the transfer gate electrode TG.

The length L2 of the second conductor portion TG2 is longer than the length L1 of the first conductor portion TG1, where L1 is the length of the first conductor portion TG1 in the gate length direction of the transfer gate electrode TG (that is, a direction parallel to straight line A′-B), and L2 is the length of the second conductor portion TG2 in the gate length direction. The center CL1 of the first conductor portion TG1 is located closer to the floating diffusion than the center CL2 of the second conductor portion TG2 is, where CL1 is the center of the first conductor portion TG1 in the gate length direction of the transfer gate electrode TG, and CL2 is the center of the second conductor portion TG2 in the gate length direction. This makes it easy to form the channel region 140 near the floating diffusion.

The first conductor portion TG1 is line-symmetrical with respect to a straight line (that is, straight line A′-B) that is parallel to the gate length direction of the transfer gate electrode TG and passes through the center of the transfer gate electrode TG in the gate width direction. This makes it easy to widen the width of the channel region 140 formed directly under the first conductor portion TG1, making it easy to increase the transfer efficiency of charge e⁻ from the photodiode PD to the floating diffusion FD.

As illustrated in FIG. 7A, in the imaging device 1 according to the present embodiment, a P-type region 130 may be partially provided in the pixel separating portion 117. For example, the P-type region 130 electrically connects the P-well layer 115 located on the front surface side of one of adjacent pixels 541 and the P-well layer 115 located on the front surface side of the other pixel 541. The P-type concentration in the P-type region 130 is lower than the P-type concentration in the P well layer 115.

This makes it possible to lower the potential barrier between the adjacent pixels 541, making it easy for the charge e⁻ to move from one of the adjacent pixels to the other pixel. For example, a pair of pixels 541 adjacent in the row direction (H direction) may be used as a single pixel of the same color. In this case, the outputs of the pair of pixels 541 adjacent in the H direction are combined to generate an output of the single pixel. The P-type region 130 lowers the potential barrier between the pair of pixels 541, making it possible for the charge e⁻ to move from one pixel 541 to the other pixel 541 before the charge e⁻ overflows in the one pixel 541. As a result, the output of one pixel output from the pair of pixels 541 can be more linear with respect to the amount of light received.

### Comparative Example

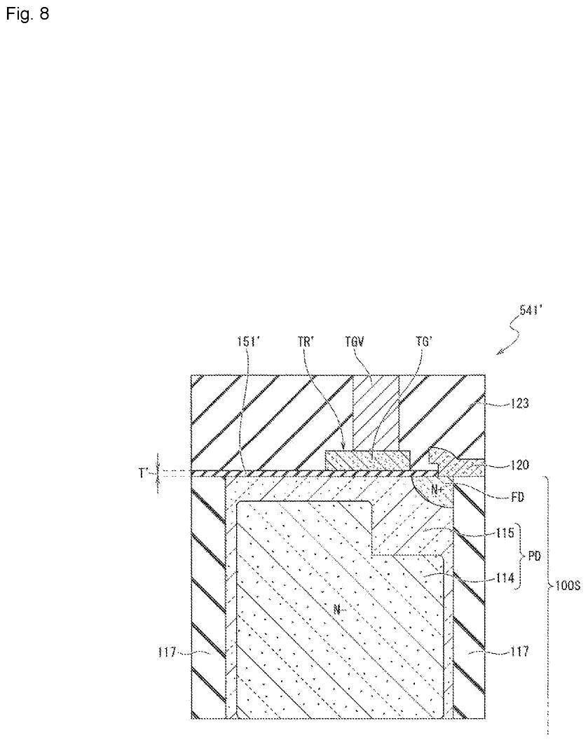

FIG. 8 is a cross-sectional view illustrating a configuration example of a pixel 541′ according to a comparative example of the present disclosure. As illustrated in FIG. 8, the pixel 541′ according to the comparative example includes a transfer transistor TR′. Unlike the transfer gate electrode TG of the embodiment, the transfer gate electrode TG′ of the transfer transistor TR′ is composed of only a flat conductor portion (e.g., the second conductor portion TG2). In addition, an insulating film 151′ is arranged between the transfer gate electrode TG′ and the semiconductor layer 100S.

### (Comparison of Transfer Gate Electrode Capacitance)

The present discloser compared the capacitance of the transfer gate electrode TG of the transfer transistor TR according to the embodiment illustrated in FIGS. 7A and 7B with the capacitance of the transfer gate electrode TG′ of the transfer transistor TR′ according to the comparative example illustrated in FIG. 8.

In this comparison, for the transfer transistor TR according to the embodiment, the thickness T1 of the insulating film 151 was 6.5 nm, the thickness T2 of the insulating film 152 was 180 nm, and the dielectric constant of the insulating films 151 and 152 was 3.9. Further, in the transfer transistor TR, the area of the first conductor portion TG1 in plan view was 0.02 μm², and the area of the second conductor portion TG2 in plan view was 0.112 μm². It was assumed that the semiconductor layer 100S was a Si substrate and was a conductor. Under these conditions, the capacitance of the transfer gate electrode TG was simply calculated to be 0.124 fF.

For the transfer transistor TR′ according to the comparative example, the thickness T′ of the insulating film 151′ was 6.5 nm, the dielectric constant of the insulating film 151 was 3.9, and the area of the transfer gate electrode TG′ in plan view was 0.112 μm². Under these conditions, the capacitance of the transfer gate electrode TG′ was simply calculated to be 0.595 fF.

If the capacitance of the transfer gate electrode TG′ according to the comparative example is 1, the capacitance of the transfer gate electrode TG according to the embodiment is 0.21. From this result, it was confirmed that the transfer gate electrode TG according to the embodiment had a lower capacitance than the transfer gate electrode TG′ according to the comparative example.

### Advantageous Effect of Embodiment

As described above, the imaging device 1 according to the embodiment of the present disclosure includes a semiconductor layer 100S (an example of a “first substrate” of the present disclosure) and a plurality of pixels 541 provided in the semiconductor layer 100S. Each of the plurality of pixels 541 includes a photodiode PD (an example of a “photoelectric conversion portion” in the present disclosure) provided in the semiconductor layer 100S, a floating diffusion FD (an example of a “charge storage portion” in the present disclosure) provided in the semiconductor layer 100S, and a transfer transistor TR provided on the front surface side (an example of a “front surface” in the present disclosure) of the semiconductor layer 100S to transfer a charge e⁻ from the photodiode PD to the floating diffusion FD. The transfer transistor TR has a transfer gate electrode TG provided on the front surface of the semiconductor layer 100S with an insulating film 150 interposed therebetween. The insulating film 150 includes a first insulating film located on the channel region 140 formed in the semiconductor layer 100S, and a second insulating film located on a region other than the channel region 140 in the semiconductor layer 100S. For example, the first insulating film is the insulating film 151. The second insulating film is a laminated film in which the insulating film 152 is laminated on the insulating film 151. The second insulating film is thicker than the first insulating film.

According to this, it is possible to reduce a part of a capacitance generated between the transfer gate electrode TG and the semiconductor layer 100S, the part being a capacitance between a portion located on the second insulating film (e.g., the second conductor portion TG2) and the semiconductor layer 100S. As a result, the capacitance of the transfer gate electrode TG can be reduced compared to a case where the first insulating film and the second insulating film have the same thickness (e.g., the comparative example illustrated in FIG. 8). Accordingly, for example, the settling time of the transfer transistor TR can be reduced, making it possible to increase the speed of the transfer transistor TR.

In addition, it is possible to reduce the capacitance of the transfer gate electrode TG while ensuring a large area of the connection of the transfer gate electrode TG to the through electrode TGV. To explain in detail, in terms of manufacturing technology, it is highly difficult to form through-holes with a small diameter in the interlayer insulating film 123 or the insulating region 212, and embed an electrode material in such a small diameter through-hole without any gaps, in the imaging device 1, which includes a laminated structure in which the second substrate 200 is laminated on the first substrate 100, as illustrated in FIG. 4. Therefore, there is a limit to reducing the diameter of the through electrode TGV that penetrates through the interlayer insulating film 123 and others, and thus, the through electrode TGV is formed to have a certain diameter or larger. Therefore, the area of the connection of the transfer gate electrode TG to the through electrode TGV also needs to have a certain value or larger. In the comparative example, it is necessary to form a large transfer gate electrode TG′ to secure the area of the connection to the through electrode TGV, and accordingly, the transfer gate electrode TG′ has a large capacitance.

In contrast, in the imaging device 1 according to the embodiment of the present disclosure, the transfer gate electrode TG includes the first conductor portion TG1 and the second conductor portion TG2. The capacitance per unit area of the second conductor portion TG is smaller than the capacitance per unit area of the first conductor portion TG1. This makes it possible to reduce the capacitance of the transfer gate electrode TG while ensuring a large area of the connection between the transfer gate electrode TG and the through electrode TGV.

In the imaging device 1 according to the embodiment of the present disclosure, it is preferable that the pad portion 120 is located closer to the semiconductor layer 100S than the second conductor portion TG2 of the transfer gate electrode TG is, as illustrated in FIG. 7B. This makes it possible to increase the distance between the second conductor portion TG2 and the pad portion 120 as compared to a case where the second conductor portion TG2 and the pad portion 120 are flushed, so that the capacitance generated between the second conductor portion TG2 and the pad portion 120 can be reduced.

### Modification Example 1

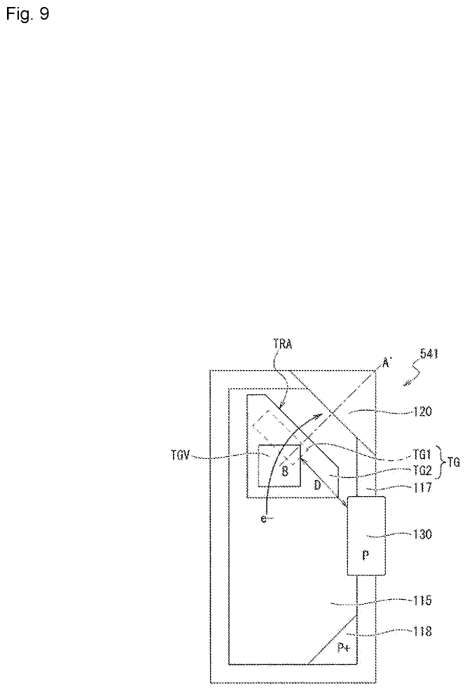

FIG. 9 is a plan view illustrating Modification example 1 of a pixel 541 according to the embodiment of the present disclosure. In Modification example 1 illustrated in FIG. 9, the pixel 541 includes a transfer transistor TRA. Unlike the transfer transistor TR illustrated in FIGS. 7A and 7B, the transfer transistor TRA is asymmetrical with respect to straight line A′-B. In the transfer transistor TRA, a distance D between the first conductor portion and the P-type region 130 is longer than that in the transfer transistor TR. This makes it possible to prevent the potential of the first conductor portion TG1 from influencing the potential of the P-type region 130. Fluctuations in charge transfer characteristics through the P-type region 130 can be suppressed.

### Modification Example 2

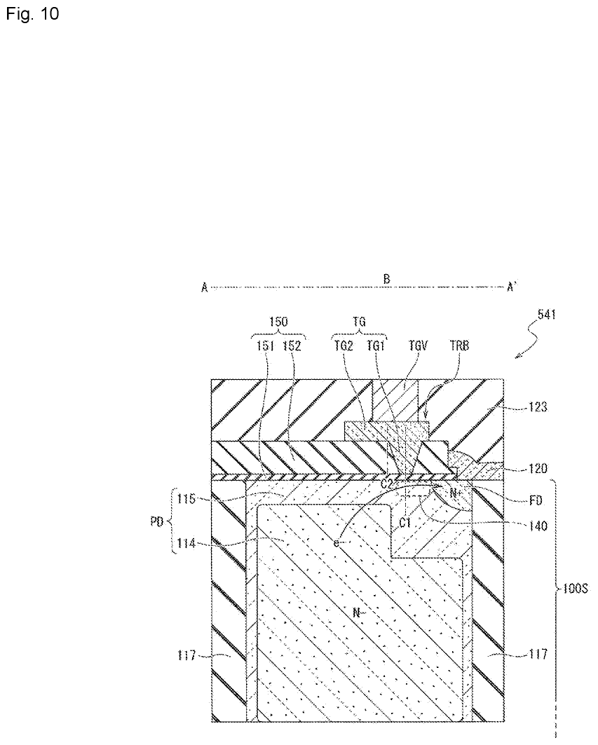

FIG. 10 is a plan view illustrating Modification example 2 of a pixel 541 according to the embodiment of the present disclosure. In Modification example 2 illustrated in FIG. 10, the pixel 541 includes a transfer transistor TRB. The first conductor portion TG1 of the transfer transistor TRB has a tapered shape with a diameter gradually decreasing from the second conductor portion TG2 toward the semiconductor layer 100S. According to this, it is possible to reduce the area of the contact between the first conductor portion TG1 and the insulating film 151, making it possible to further reduce the capacitance between the first conductor portion TG1 and the semiconductor layer 100S. In addition, the first conductor portion TG1 can be smoothly connected to the second conductor portion TG2 with a reduced capacitance between the first conductor portion TG1 and the semiconductor layer 100S.

The tapered first conductor portion TG1 is easy to manufacture because it can be formed in a manner that, for example, etching is performed on the insulating film 152 using a mask such that side etching progresses to form a connection via having a tapered inner surface, and then a conductive material (e.g., doped polysilicon added with an impurity) is deposited in the formed connection via.

### Modification Example 3

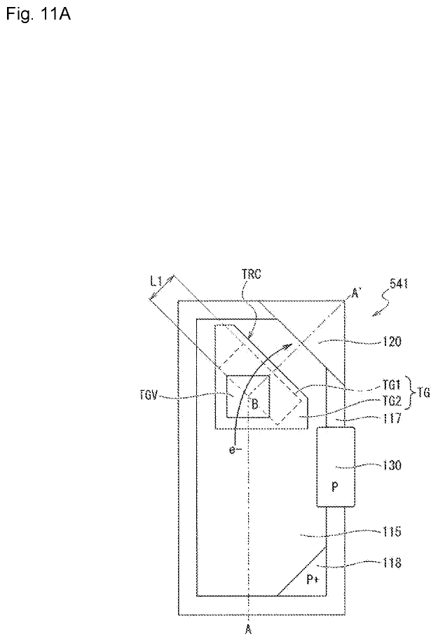

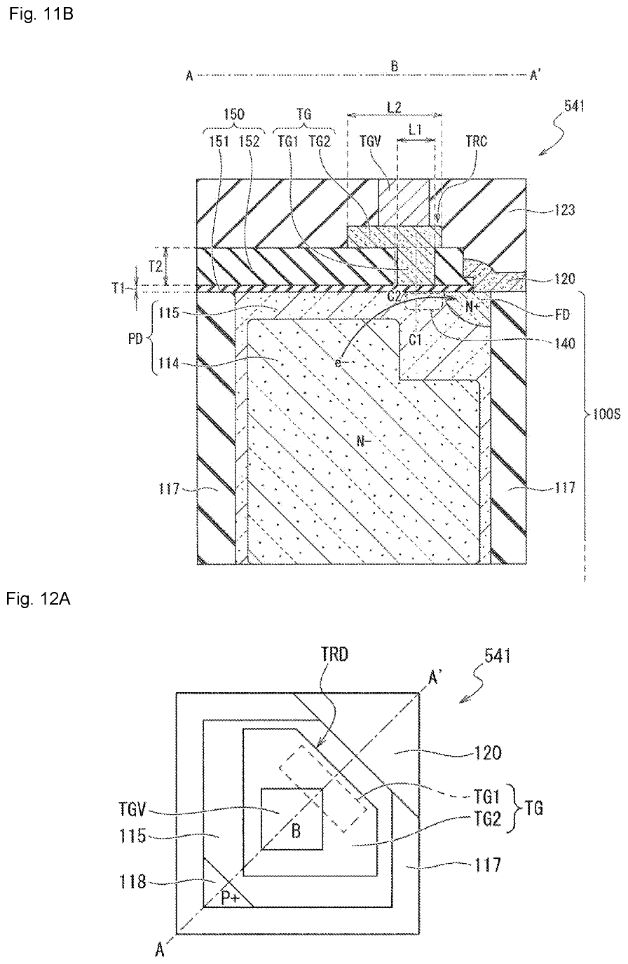

FIGS. 11A and 11B are a plan view and a cross-sectional view illustrating Modification example 3 of a pixel 541 according to the embodiment of the present disclosure, respectively. In Modification example 3 illustrated in FIGS. 11A and 11B, the pixel 541 includes a transfer transistor TRC. In the transfer transistor TRC, the length L1 of the first conductor portion TG1 in the gate length direction is longer than that of the transfer transistor TR illustrated in FIGS. 7A and 7B. According to this, the capacitance of the transfer gate electrode TG increases compared to the transfer transistor TR illustrated in FIGS. 7A and 7B, but it is easier to turn on/off the current by means of gate modulation.

### Modification Example 4

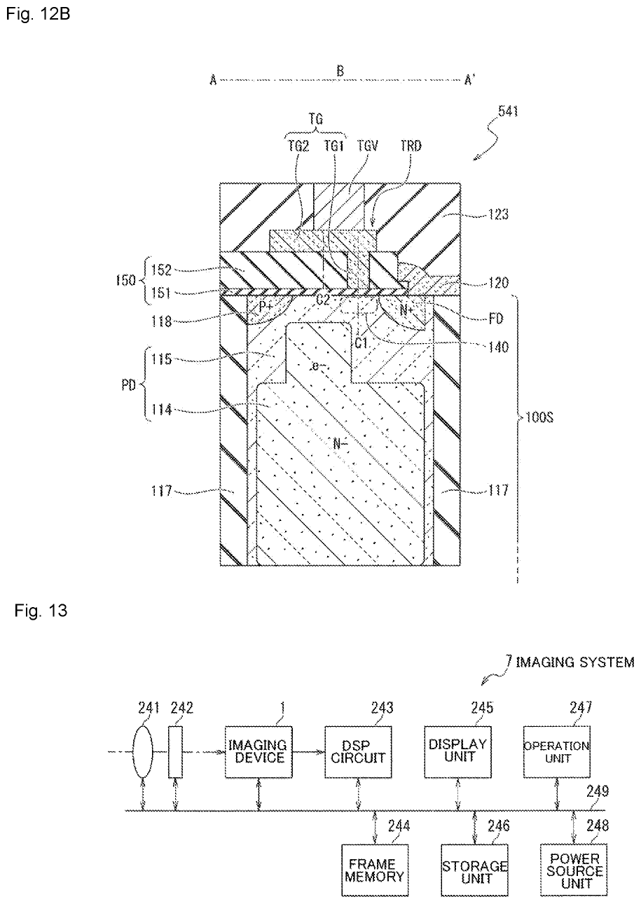

FIGS. 12A and 12B are a plan view and a cross-sectional view illustrating Modification example 4 of a pixel 541 according to the embodiment of the present disclosure, respectively. In Modification example 4 illustrated in FIGS. 12A and 12B, the pixel 541 has a square shape or a shape close to a square in plan view. The pixel 541 also includes a transfer transistor TRD. Like the transfer transistor TR illustrated in FIGS. 7A and 7B, also in the transfer transistor TRD illustrated in FIGS. 12A and 12B, the capacitance of the transfer gate electrode TG can be reduced because the transfer gate electrode TG includes the first conductor portion TG1 and the second conductor portion TG2. The pixel 541 has a square shape or a shape close to a square in plan view. The shape of the pixel 541 is a normal type, making it easy to increase the number of pixels.

### Other Embodiments

While the present disclosure has been described with the embodiment and modification examples as described above, the descriptions and figures that form parts of the present disclosure should not be understood as limiting the present disclosure. Various alternative embodiments, implementations, and operational technologies will be apparent to those skilled in the art from the present disclosure. Of course, the technology according to the present disclosure (the present technology) includes various embodiments not described herein.

For example, while it has been described that four pixels constitute one shared pixel structure in the embodiment described above, the present technology is not limited thereto. In the present technology, the pixels need not constitute a shared pixel structure. Specifically, one pixel may be constituted of one photodiode PD, one transfer transistor TR, one floating diffusion FD, one reset transistor RST, and one amplifier transistor AMP, or one pixel may be constituted of one selection transistor SEL in addition to the elements listed above.

The embodiment has been described above in which the imaging device 1 includes the first substrate 100 and the second substrate 200 bonded to the front surface side of the first substrate 100; photodiodes PD, floating diffusions FD, transfer transistors TR, and others are formed in the first substrate 100; and the pixel circuits 210 each including the amplifier transistor AMP and others are formed in the second substrate 200. However, the present technology is not limited thereto. In the present technology, the first substrate 100 and the second substrate 200 may be configured as one substrate. The photodiodes PD, the floating diffusions FD, the transfer transistors TR, the pixel circuits 210, and others may be formed in one substrate. Then, the third substrate 300 in which the image signal processing unit 560 and others are formed may be bonded to this one substrate.

The present technology includes, as an example, the following applicable/application examples.

### Applicable Example

FIG. 13 is a diagram illustrating an example of a schematic configuration of an imaging system 7 including the imaging device 1 according to the embodiment and the modification examples.

The imaging system 7 is an electronic device, for example, an imaging device such as a digital still camera or a video camera, or a portable terminal device such as a smartphone or a tablet terminal. The imaging system 7 includes, for example, the imaging device 1 according to the embodiment and its modification examples described above, a DSP circuit 243, a frame memory 244, a display unit 245, a storage unit 246, an operation unit 247, and a power supply unit 248. In the imaging system 7, the imaging device 1 according to the embodiment and its modification examples described above, the DSP circuit 243, the frame memory 244, the display unit 245, the storage unit 246, the operation unit 247, and the power supply unit 248 are connected to each other through a bus line 249.

The imaging device 1 according to the embodiment and its modification examples described above outputs image data corresponding to incident light. The DSP circuit 243 is a signal processing circuit that processes signals (image data) output from the imaging device 1 according to the above embodiment and its modification examples described above. The frame memory 244 temporarily holds the image data processed by the DSP circuit 243 in units of frames. The display unit 245 includes a panel type display device such as a liquid crystal panel or an organic electro luminescence (EL) panel, and displays moving images or still images captured by the imaging device 1 according to the embodiment and its modification examples described above. The storage unit 246 records therein image data of a moving image or a still image captured by the imaging device 1 according to the embodiment and its modification examples described above on a recording medium such as a semiconductor memory or a hard disk. The operation unit 247 issues an operation command for various functions of the imaging system 7 in response to operations of a user. The power supply unit 248 supplies, as appropriate, various power sources that serve as operating power sources for the imaging device 1 according to the embodiment and its modification examples describe above, the DSP circuit 243, the frame memory 244, the display unit 245, the storage unit 246, and the operation unit 247.

The imaging steps in the imaging system 7 will be described below.

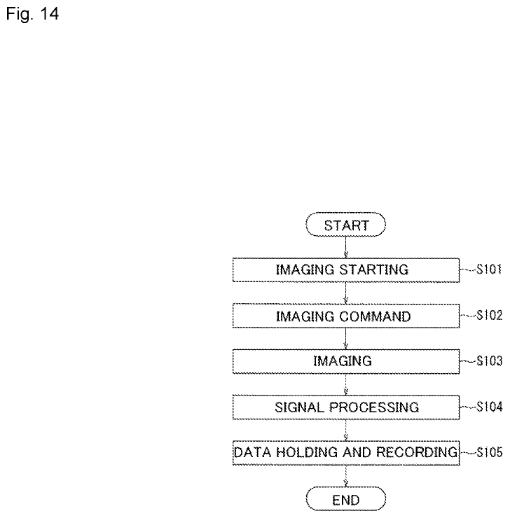

FIG. 14 is a flowchart illustrating an example of the imaging operation in the imaging system 7. The user instructs to start imaging by operating the operation unit 247 (step S101). Then, the operation unit 247 transmits an imaging command to the imaging device 1 (step S102). When receiving the imaging command, the imaging device 1 (specifically, a system control circuit 36) executes imaging using a predetermined imaging method (step S103).

The imaging device 1 outputs image data obtained by imaging to the DSP circuit 243. As used herein, the image data is data of pixel signals generated for all pixels based on charges temporarily held in the floating diffusions FD. The DSP circuit 243 performs predetermined signal processing (e.g., noise reduction processing) based on the image data input from the imaging device 1 (step S104). The DSP circuit 243 causes the frame memory 244 to hold the image data that has undergone predetermined signal processing, and the frame memory 244 causes the storage unit 246 to store the image data (step S105). In this way, the imaging is performed in the imaging system 7.

In this applicable example, the imaging device 1 according to the embodiment and its modification examples described above is applicable to the imaging system 7. As a result, the capacitance of the transfer gate electrode in the imaging device 1 can be reduced, and thus, the transfer characteristics of image signals can be improved, so that a high-performance imaging system 7 can be provided.

### APPLICATION EXAMPLES

### Application Example 1

The technology of the present disclosure (the present technology) can be applied to various products. For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

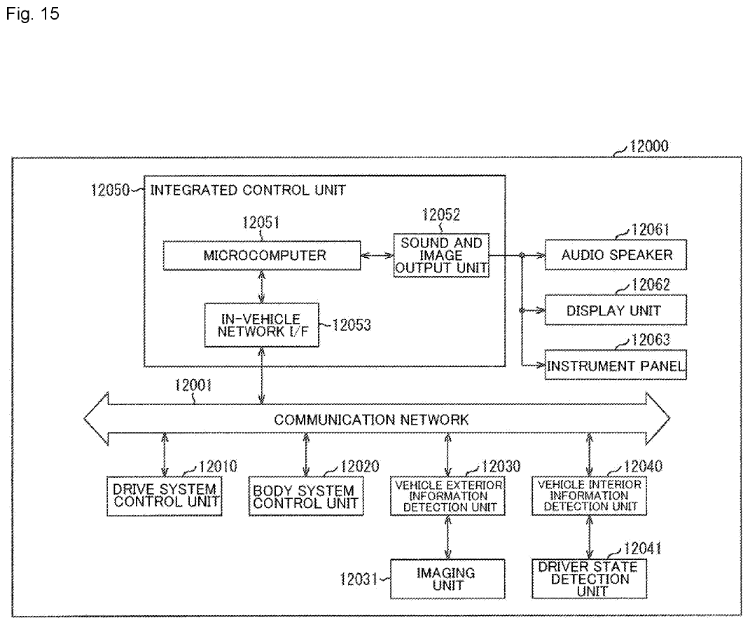

FIG. 15 is a block diagram illustrating a schematic configuration example of a vehicle control system, which is an example of a moving body control system to which the technology according to the present disclosure can be applied.

The vehicle control system 12000 includes a plurality of electronic control units connected thereto via a communication network 12001. In the example illustrated in FIG. 15, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound and image output unit 12052, and an in-vehicle network interface (I/F) 12053 are illustrated.

The drive system control unit 12010 controls operations of devices related to a drive system of a vehicle according to various programs. For example, the drive system control unit 12010 functions as a control device for a driving force generation device for generating the driving force of the vehicle such as an internal combustion engine or a drive motor, a driving force transmission mechanism for transmitting the driving force to the wheels, a steering mechanism for adjusting the steering angle of the vehicle, a braking device for generating the braking force of the vehicle, or the like.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle equipped with the vehicle control system 12000. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road on the basis of the received image.

The imaging unit 12031 is an optical sensor that receives light and outputs an electrical signal corresponding to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound and image output unit 12052 transmits an output signal of at least one of sound and an image to an output device capable of visually or audibly notifying a passenger or the outside of the vehicle of information. In this example, an audio speaker 12061, a display unit 12062, and an instrument panel 12063 are exemplified as output devices. The display unit 12062 may include at least one of an on-board display and a head-up display, for example.

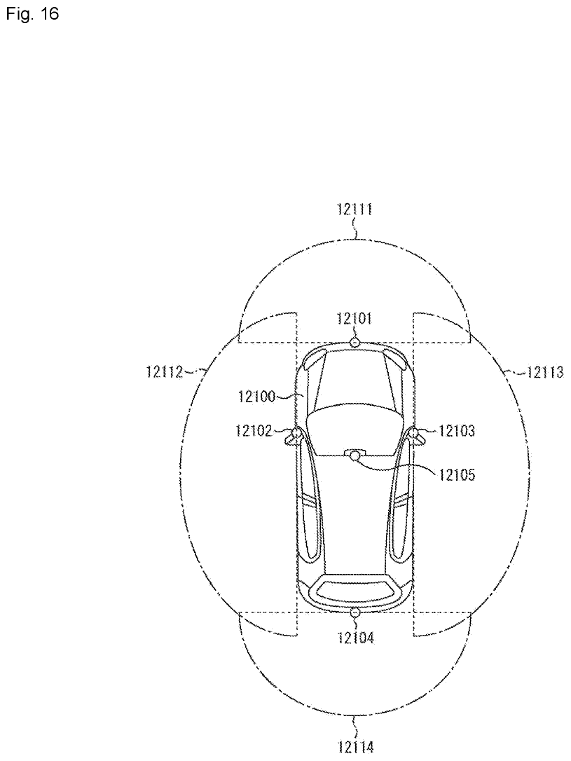

FIG. 16 is a diagram illustrating an example of installation positions of imaging units 12031.

In FIG. 16, a vehicle 12100 includes imaging units 12101, 12102, 12103, 12104, and 12105 as the imaging units 12031.

The imaging units 12101, 12102, 12103, 12104, and 12105 are provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of the front of the vehicle 12100. The imaging units 12102 and 12103 provided on the side-view mirrors mainly acquire images of a lateral side of the vehicle 12100. The imaging unit 12104 provided on the rear bumper or the back door mainly acquires images of the rear of the vehicle 12100. Front view images acquired by the imaging units 12101 and 12105 are mainly used for detection of preceding vehicles, pedestrians, obstacles, traffic lights, traffic signs, lanes, and the like.

FIG. 16 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, a bird's-eye-view image of the vehicle 12100 as viewed from above can be obtained by superimposing pieces of image data captured by the imaging units 12101 to 12104.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 acquires a distance to each of three-dimensional objects in the imaging ranges 12111 to 12114 and temporal change in the distance (a relative speed with respect to the vehicle 12100) on the basis of the distance information obtained from the imaging units 12101 to 12104, thereby extracting, as a vehicle ahead, a closest three-dimensional object particularly on a path along which the vehicle 12100 is traveling, that is, a three-dimensional object traveling at a predetermined speed (e.g., 0 km/h or higher) in the substantially same direction as the vehicle 12100. Furthermore, the microcomputer 12051 can set an inter-vehicle distance to be secured in front of the vehicle in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on an operation of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in captured images of the imaging units 12101 to 12104. Such recognition of the pedestrian is performed using, for example, a procedure for extracting feature points in the captured images of the imaging units 12101 to 12104 serving as infrared cameras, and a procedure for performing pattern matching processing on a series of feature points indicating a contour of an object to determine whether the object is a pedestrian. When the microcomputer 12051 determines that pedestrians are in the images captured by the imaging units 12101 to 12104 and recognizes the pedestrians, the sound and image output unit 12052 controls the display unit 12062 such that rectangular contour lines for emphasis are superimposed and displayed on the recognized pedestrians. In addition, the sound and image output unit 12052 may control the display unit 12062 so that an icon indicating a pedestrian or the like is displayed at a desired position.

An example of the moving body control system to which the technology according to the present disclosure can be applied has been described above. The technology of the present disclosure can be applied to the imaging unit 12031 in the above-described configurations. More specifically, the imaging device 1 according to the embodiment and its modification examples described above can be applied to the imaging unit 12031. By applying the technology according to the present disclosure to the imaging unit 12031, the capacitance of the transfer gate electrode in the imaging unit 12031 can be reduced, and thus, the transfer characteristics of image signals can be improved, so that highly accurate control using captured images can be performed.

### Application Example 2

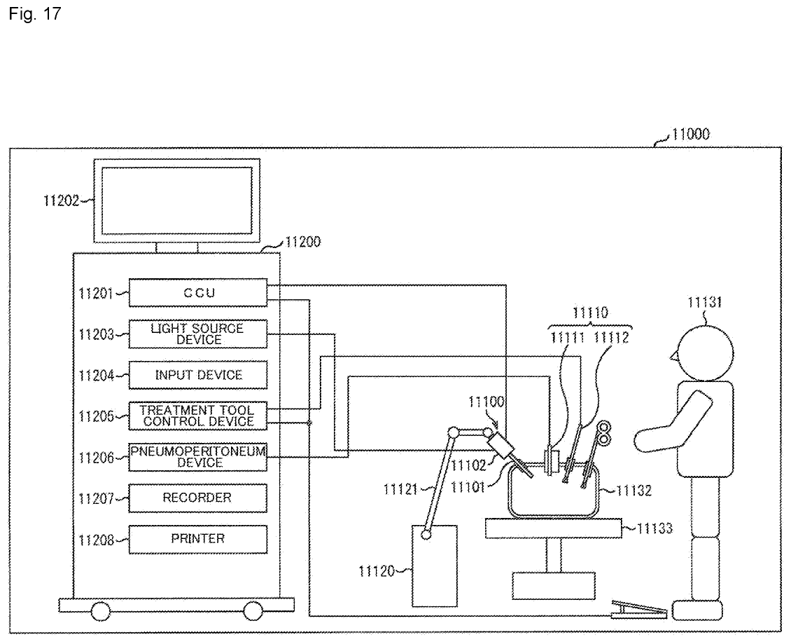

FIG. 17 is a diagram illustrating an example of a schematic configuration of an endoscope surgery system to which the technology according to the present disclosure (the present technology) is applied.

FIG. 17 illustrates a state where an operator (doctor) 11131 is using an endoscopic surgery system 11000 to perform a surgical operation on a patient 11132 on a patient bed 11133. As illustrated, the endoscopic surgery system 11000 includes an endoscope 11100, other surgical instruments 11110 such as a pneumoperitoneum tube 11111 and an energized treatment tool 11112, a support arm device 11120 that supports the endoscope 11100, and a cart 11200 mounted with various devices for endoscopic surgery.

The endoscope 11100 includes a lens barrel 11101 of which a region having a predetermined length from a distal end is inserted into a body cavity of the patient 11132, and a camera head 11102 connected to a proximal end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light irradiates an object to be observed in the body cavity of the patient 11132 through the objective lens. The endoscope 11100 may be a direct-viewing endoscope, an oblique-viewing endoscope, or a side-viewing endoscope.

The camera head 11102 includes an optical system and an imaging element. Reflected light (observation light) from an object to be observed is condensed on the image sensor by the optical system. The observation light is photoelectrically converted by the imaging element, and an electric signal corresponding to the observation light, that is, an image signal corresponding to an observed image is generated. The image signal is transmitted as RAW data to a camera control unit (CCU) 11201.

The CCU 11201 is configured of a central processing unit (CPU), a graphics processing unit (GPU), and the like and comprehensively controls the operation of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 is configured of, for example, a light source such as a light emitting diode (LED) and supplies irradiation light, which is used when a surgical part or the like is imaged, to the endoscope 11100.

An input device 11204 is an input interface for the endoscopic surgery system 11000. The user is allowed to input various types of information or instructions to the endoscopic surgery system 11000 via the input device 11204. For example, the user inputs an instruction to change imaging conditions (a type of irradiation light, a magnification, a focal length, or the like) of the endoscope 11100.

A treatment tool control device 11205 controls driving of the energized treatment tool 11112 for cauterization or incision of a tissue, sealing of blood vessel, or the like. A pneumoperitoneum device 11206 delivers a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies the endoscope 11100 with the irradiation light for imaging the surgical site can be configured of, for example, an LED, a laser light source, or a white light source configured of a combination thereof. When a white light source is formed by a combination of RGB laser light sources, it is possible to control an output intensity and an output timing of each color (each wavelength) with high accuracy, and thus the light source device 11203 can adjust white balance of the captured image. Further, in this case, laser light from each of the respective RGB laser light sources irradiates the object to be observed in a time division manner, and driving of the imaging element of the camera head 11102 is controlled in synchronization with irradiation timing such that images corresponding to respective RGB can be captured in a time division manner. According to this method, it is possible to obtain a color image without providing a color filter in the imaging element.

Further, driving of the light source device 11203 may be controlled so that an intensity of output light is changed at predetermined time intervals. The driving of the image sensor of the camera head 11102 is controlled in synchronization with a timing of changing the intensity of the light, and images are acquired in a time division manner and combined, such that an image having a high dynamic range without so-called blackout and whiteout can be generated.

In addition, the light source device 11203 may have a configuration in which light in a predetermined wavelength band corresponding to special light observation can be supplied. In the special light observation, for example, by emitting light in a band narrower than that of irradiation light (i.e., white light) during normal observation using wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source device 11203 may have a configuration in which narrow band light and/or excitation light corresponding to such special light observation can be supplied.

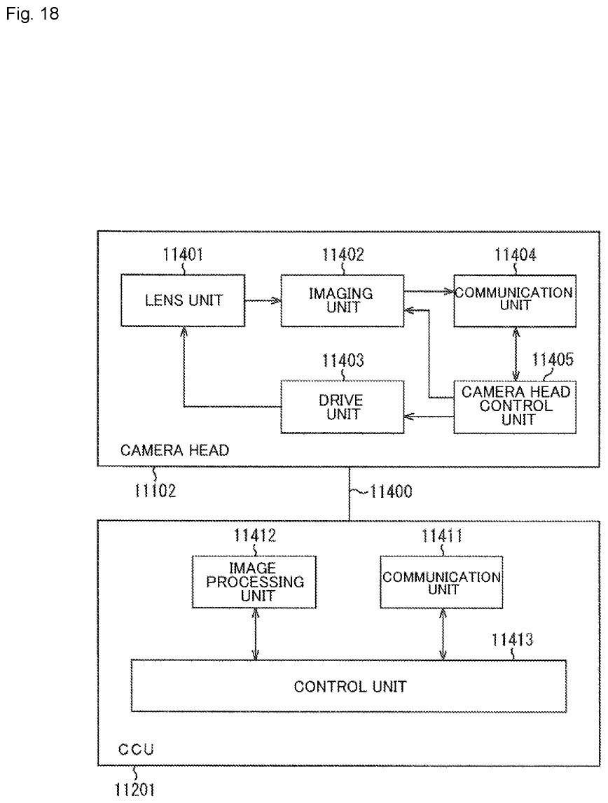

FIG. 18 is a block diagram illustrating an example of functional configurations of the camera head 11102 and the CCU 11201 illustrated in FIG. 17.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light taken from a distal end of the lens barrel 11101 is guided to the camera head 11102 and is incident on the lens unit 11401. The lens unit 11401 is configured in combination of a plurality of lenses including a zoom lens and a focus lens.

The imaging unit 11402 is configured of an imaging element. The imaging unit 11402 may be configured of one imaging element (so-called single plate type) or a plurality of imaging elements (so-called multi-plate type). For the imaging unit 11402 of multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. With 3D display performed, the operator 11131 can ascertain the depth of biological tissues in the surgical site more accurately. For the imaging unit 11402 of multi-plate type, a plurality of systems of lens units 11401 may be provided in correspondence to the image sensors.

The imaging unit 11402 need not necessarily be provided in the camera head 11102. For example, the imaging unit 11402 may be provided immediately after the objective lens inside the lens barrel 11101.

The drive unit 11403 is configured of an actuator and the zoom lens and the focus lens of the lens unit 11401 are moved by a predetermined distance along an optical axis under the control of the camera head control unit 11405. Accordingly, the magnification and focus of the image captured by the imaging unit 11402 can be adjusted appropriately.

The communication unit 11404 is configured of a communication device for transmitting and receiving various types of information to and from the CCU 11201. The communication unit 11404 transmits the image signal obtained from the imaging unit 11402 as RAW data to the CCU 11201 via the transmission cable 11400.

Further, the communication unit 11404 receives a control signal for controlling driving of the camera head 11102 from the CCU 11201 and supplies the control signal to the camera head control unit 11405. The control signal includes, for example, information regarding imaging conditions such as information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, a so-called auto focus (AF) function, and a so-called auto white balance (AWB) function are provided in the endoscope 11100.

The camera head control unit 11405 controls driving of the camera head 11102 on the basis of a control signal from the CCU 11201 received via the communication unit 11404.

The communication unit 11411 is configured of a communication device for transmitting and receiving various types of information to and from the camera head 11102. The communication unit 11411 receives the image signal transmitted from the camera head 11102 via the transmission cable 11400.

Further, the communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various kinds of control on imaging of the surgical site or the like by the endoscope 11100 and display of a captured image obtained through imaging of the surgical or the like. For example, the control unit 11413 generates the control signal for controlling the driving of the camera head 11102.

Further, the control unit 11413 causes the display device 11202 to display the captured image of the surgical site or the like on the basis of the image signal subjected to the image processing in the image processing unit 11412. In this case, the control unit 11413 may recognize various objects in the captured image using various image recognition techniques. For example, the control unit 11413 can detect a shape, color, or the like of edges of the object included in the captured image to recognize surgical tools such as forceps, a specific living body portion, bleeding, a mist when the energized treatment tool 11112 is used, or the like. When the control unit 11413 causes the display device 11202 to display the captured image, the control unit 11413 may cause various types of surgery assistance information to be superimposed on the image of the surgical site and displayed using a result of the recognition. By displaying the surgery support information in a superimposed manner and presenting it to the operator 11131, a burden on the operator 11131 can be reduced, and the operator 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of the endoscopic surgery system to which the technology according to the present disclosure can be applied has been described above. The technology according to the present disclosure can be suitably applied to the imaging unit 11402 provided in the camera head 11102 of the endoscope 11100 among the configurations described above. By applying the technology according to the present disclosure to the imaging unit 11402, the capacitance of the transfer gate electrode in the imaging unit 11402 can be reduced, and thus, the transfer characteristics of image signals can be improved, so that a high-performance endoscope 11100 can be provided.

As described above, the present technology enables at least one of various omissions, substitutions, and modifications of constituent elements to be performed without departing from the spirit and scope of the embodiment described above. Furthermore, the advantageous effects described in the present specification are merely exemplary and not intended as limiting, and other advantageous effects may be produced.

The present disclosure can also be configured as follows.

(1)

An imaging device, including
a first substrate; and
a plurality of pixels that are provided in the first substrate,
wherein each of the plurality of pixels includes
a photoelectric conversion portion that is provided in the first substrate,
a charge storage portion that is provided in the first substrate, and
a transfer transistor that is provided on a first surface side of the first substrate to transfer charges from the photoelectric conversion portion to the charge storage portion,
the transfer transistor includes
a transfer gate electrode that is provided on the first surface of the first substrate via an insulating film interposed between the transfer gate electrode and the first surface,
the insulating film includes
a first insulating film that is located on a channel region formed on the first substrate, and
a second insulating film that is located on a region other than the channel region on the first substrate, and
the second insulating film is thicker than the first insulating film.

(2)

The imaging device according to (1), wherein
the transfer gate electrode includes
a first conductor portion that is located on the first insulating film, and
a second conductor portion that is connected to the first conductor portion and located on the second insulating film.

(3)

An imaging device, including:
a first substrate; and
a plurality of pixels that are provided in the first substrate,
wherein each of the plurality of pixels includes
a photoelectric conversion portion that is provided in the first substrate,
a charge storage portion that is provided in the first substrate, and
a transfer transistor that is provided on a first surface side of the first substrate to transfer charges from the photoelectric conversion portion to the charge storage portion,
the transfer transistor includes
a transfer gate electrode that is provided on the first surface of the first substrate via an insulating film interposed between the transfer gate electrode and the first surface,
the transfer gate electrode includes
a first conductor portion, and
a second conductor portion that is connected to the first conductor portion,
the insulating film includes
a first insulating film that is located between the first substrate and the first conductor portion, and
a second insulating film that is located between the first substrate and the second conductor portion, and
the second insulating film is thicker than the first insulating film.

(4)

The imaging device according to (2) or (3), wherein the first conductor portion is located between the first substrate and the second conductor portion.

(5)

The imaging device according to (4), wherein a center of the first conductor portion in a gate length direction of the transfer gate electrode is located closer to the charge storage portion than a center of the second conductor portion in the gate length direction is.

(6)

The imaging device according to any one of (2) to (5), further including a shared conductor that is provided on the first surface side of the first substrate and shared between adjacent pixels among the plurality of pixels, wherein the shared conductor is connected to the charge storage portion of one of the adjacent pixels and the charge storage portion of the other of the adjacent pixels.

(7)

The imaging device according to (6), further including:
an interlayer insulating film that is provided on the first surface side of the first substrate;
a second substrate that faces the first substrate via the interlayer insulating film; and
an amplifier transistor that is provided in the second substrate to amplify a charge transferred from the first substrate to the second substrate through the shared conductor.

(8)

The imaging device according to (6) or (7), wherein the shared conductor is located closer to the first substrate than the second conductor portion is.

(9)

The imaging device according to (7) or (8), further including a through electrode that penetrates through the interlayer insulating film and connects to the second conductor portion.

### REFERENCE SIGNS LIST

1 Imaging device
7 Imaging system
36 System control circuit
100 First substrate
100S, 200S, 300S Semiconductor layer
100T, 200T, 300T Wiring layer
111, 117B, 150, 151, 152 Insulating film
112 Fixed charge film
113 First pinning region
114 n-type semiconductor region
115 P-well layer
116 Second pinning region
117 Pixel separating portion
117A Light shielding film
118 VSS contact region
119, 123 Interlayer insulating film
120, 121 Pad portion
120C, 121C Connection via
120E, 121E Through electrode
121 Pad portion
122 Passivation film
124 Bonding film
130 P-type region
140 Channel region
200 Second substrate
200S, 300S Semiconductor layer
200T, 300T Wiring layer
201, 202, 301, 302 Contact portion
201R, 202R, 301R, 302R Contact region
210 Pixel circuit
211 Well region
212 Insulating region
243 DSP circuit
244 Frame memory
245 Display unit
246 Storage unit
247 Operation unit
248 Power supply unit
249 Bus line
300 Third substrate
401 Light receiving lens
510A Input unit
510B Output unit
520 Row drive unit
530 Timing control unit
539 Pixel share unit
540 Pixel array unit
540B Peripheral unit
541, 541A, 541B, 541C, 541D Pixel
542 Row drive signal line
543 Vertical signal line (column readout line)
544 Power supply line
550 Column signal processing unit
560 Image signal processing unit
11000 Endoscopic operation system
11100 Endoscope
11101 Lens barrel
11102 Camera head
11110 Surgical instrument
11111 Pneumoperitoneum tube
11112 Energized treatment tool
11120 Support arm device
11131 Operator (doctor)
11132 Patient
11133 Patient bed
11200 Cart
11201 Camera control unit (CCU)
11202 Display device
11203 Light source device
11204 Input device
11205 Treatment tool control device
11206 Pneumoperitoneum device
11207 Recorder
11208 Printer
11400 Transmission cable
11401 Lens unit
11402, 12031, 12101, 12102, 12103, 12104, 12105 Imaging unit
11403 Drive unit
11404 Communication unit
11405 Camera head control unit
11411 Communication unit
11412 Image processing unit
11413 Control unit
12000 Vehicle control system
12001 Communication network
12010 Drive system control unit
12020 Body system control unit
12030 Vehicle exterior information detection unit
12040 Vehicle interior information detection unit
12041 Driver state detection unit
12050 Integrated control unit
12051 Microcomputer
12052 Sound and image output unit
12061 Audio speaker
12062 Display unit
12063 Instrument panel
12100 Vehicle
12111, 12112, 12113, 12114 Imaging range
AMP Amplifier transistor
CL1, CL2 Center
FD, FD1, FD2, FD3, FD4 Floating diffusion
FDG FD conversion gain switching transistor
H1, H2 Connection hole portion
L Light
PD, PD1, PD2, PD3, PD4 Photodiode
RST Reset transistor
SEL Selection transistor
T′, T1, T2 Film thickness
TA, TB External terminal
TG Transfer gate electrode
TG1 First conductor portion
TG2 Second conductor portion
TGV Through electrode
TR, TR1, TR2, TR3, TR4, TRA, TRB, TRC, TRD Transfer transistor
VDD Power supply line
VSS Reference potential line

1. An imaging device, comprising:
a first substrate;
a plurality of pixels that are provided in the first substrate,
wherein each of the plurality of pixels includes
a photoelectric conversion portion that is provided in the first substrate,
a charge storage portion that is provided in the first substrate, and
a transfer transistor that is provided on a first surface side of the first substrate to transfer charges from the photoelectric conversion portion to the charge storage portion,
the transfer transistor includes
a transfer gate electrode that is provided on the first surface of the first substrate via an insulating film interposed between the transfer gate electrode and the first surface,
the insulating film includes
a first insulating film that is located on a channel region formed on the first substrate, and
a second insulating film that is located on a region other than the channel region on the first substrate, and
the second insulating film is thicker than the first insulating film.

2. The imaging device according to claim 1, wherein
the transfer gate electrode includes
a first conductor portion that is located on the first insulating film, and
a second conductor portion that is connected to the first conductor portion and located on the second insulating film.

3. An imaging device, comprising:
a first substrate;
a plurality of pixels that are provided in the first substrate,
wherein each of the plurality of pixels includes
a photoelectric conversion portion that is provided in the first substrate,
a charge storage portion that is provided in the first substrate, and
a transfer transistor that is provided on a first surface side of the first substrate to transfer charges from the photoelectric conversion portion to the charge storage portion,
the transfer transistor includes
a transfer gate electrode that is provided on the first surface of the first substrate via an insulating film interposed between the transfer gate electrode and the first surface,
the transfer gate electrode includes
a first conductor portion, and
a second conductor portion that is connected to the first conductor portion,
the insulating film includes
a first insulating film that is located between the first substrate and the first conductor portion, and
a second insulating film that is located between the first substrate and the second conductor portion, and
the second insulating film is thicker than the first insulating film.

4. The imaging device according to claim 2, wherein the first conductor portion is located between the first substrate and the second conductor portion.

5. The imaging device according to claim 4, wherein a center of the first conductor portion in a gate length direction of the transfer gate electrode is located closer to the charge storage portion than a center of the second conductor portion in the gate length direction is.

6. The imaging device according to claim 2, further comprising a shared conductor that is provided on the first surface side of the first substrate and shared between adjacent pixels among the plurality of pixels,
wherein the shared conductor is connected to the charge storage portion of one of the adjacent pixels and the charge storage portion of the other of the adjacent pixels.

7. The imaging device according to claim 6, further comprising:
an interlayer insulating film that is provided on the first surface side of the first substrate;
a second substrate that faces the first substrate via the interlayer insulating film; and
an amplifier transistor that is provided in the second substrate to amplify a charge transferred from the first substrate to the second substrate through the shared conductor.

8. The imaging device according to claim 6, wherein the shared conductor is located closer to the first substrate than the second conductor portion is.

9. The imaging device according to claim 7, further comprising a through electrode that penetrates through the interlayer insulating film and connects to the second conductor portion.
